(19) United States
(12) Patent Application Publication
(10) Pub. No.: US 2026/0026327 A1
(43) Pub. Date: Jan. 22, 2026

(54) SEMICONDUCTOR DEVICE AND METHOD OF MANUFACTURING THE SAME

(71) Applicant: SAMSUNG ELECTRONICS CO., LTD., SUWON-SI, GYEONGGI-DO (KR)

(72) Inventors: Wonjung Jang, Suwon-si (KR); Seyong Lee, Suwon-si (KR)

(21) Appl. No.: 19/181,469

(22) Filed: Apr. 17, 2025

(30) Foreign Application Priority Data
Jul. 22, 2024 (KR) 10-2024-0096305

(51) Int. Cl. H01L 23/48; H01L 21/311; H01L 21/78; H01L 23/50; H01L 25/18

(52) U.S. Cl. CPC H01L 23/481; H01L 21/31144; H01L 21/78; H01L 23/50; H01L 25/18

(57) ABSTRACT

A semiconductor device includes: a substrate including a component area and an edge area at least partially surrounding an outer perimeter of the component area; an upper insulating layer disposed on a first surface of the substrate; a recess formed in the upper insulating layer and extends downward along an outermost perimeter of the substrate in the edge area; and a trench formed in the upper insulating layer between the component area and the recess, and recessed downward beyond the recess, in the edge area.

### CROSS-REFERENCE TO RELATED APPLICATION

This application claims priority under 35 U.S.C. § 119 to Korean Patent Application No. 10-2024-0096305 filed on Jul. 22, 2024, in the Korean Intellectual Property Office, the disclosure of which is incorporated by reference herein in its entirety.

### TECHNICAL FIELD

Various embodiments of the present inventive concept relate to a semiconductor device and a method of manufacturing the semiconductor device.

### DISCUSSION OF THE RELATED ART

Electronic devices have become lighter in weight with increased performance, which may, in turn, use semiconductor packages with reduced sizes and increased performance. To implement the semiconductor packages that are downsized, lightweight, highly performing, have a high-capacity, and are highly reliable, there have been continued efforts in research and development on a semiconductor package having a structure in which semiconductor chips are stacked in multiple layers.

### SUMMARY

According to an embodiment of the present inventive concept, a semiconductor device includes: a substrate including a component area and an edge area at least partially surrounding an outer perimeter of the component area; an upper insulating layer disposed on a first surface of the substrate; a recess formed in the upper insulating layer and extends downward along an outermost perimeter of the substrate in the edge area; and a trench formed in the upper insulating layer between the component area and the recess, and recessed downward beyond the recess, in the edge area.

According to an embodiment of the present inventive concept, a method of manufacturing a semiconductor device includes: forming a semiconductor component in a plurality of component areas that are arranged on a substrate, wherein the plurality of component areas are spaced apart from each other in the form of a grid; forming an upper insulating layer on the substrate; etching the upper insulating layer to form a recess structure that at least partially surrounds each of the component areas, wherein the recess structure is formed on a scribe lane that is disposed between the plurality of component areas; and cutting the substrate along the scribe lane to separate the plurality of component areas from each other and form a plurality of semiconductor devices, wherein the recess structure includes: a recess formed as the upper insulating layer is recessed along the scribe lane; and a pair of trenches formed as the upper insulating layer is recessed along the scribe lane on both sides of the recess, and recessed deeper than the recess.

### BRIEF DESCRIPTION OF THE DRAWINGS

The above and other aspects of the present inventive concept will become more apparent by describing in detail embodiments thereof, with reference to the accompanying drawings, in which:

FIG. 1 is a schematic cross-sectional view of a semiconductor device according to an embodiment of the present inventive concept;

FIG. 2 is an enlarged view of area A of FIG. 1;

FIG. 3 is an enlarged view of area B of FIG. 2;

FIG. 4 is a flowchart illustrating a method of manufacturing a semiconductor device according to an embodiment of the present inventive concept;

FIG. 5 is a flowchart illustrating a method of forming a recess structure according to an embodiment of the present inventive concept;

FIG. 6 is a schematic top view of a substrate being in a process of manufacturing a semiconductor device according to an embodiment of the present inventive concept;

FIGS. 7, 8, 9, 10, 11, 12, and 13 are cross-sectional views of an area corresponding to the cross-sectional view taken along a line C-C′ of FIG. 6, illustrating a process of forming a recess structure according to an embodiment of the present inventive concept;

FIG. 14 is a schematic top view of a substrate with a trench formed according to an embodiment of the present inventive concept;

FIGS. 15, 16, 17, 18, and 19 are cross-sectional views of an area corresponding to the area B of FIG. 2, illustrating a portion of a semiconductor device according to an embodiment of the present inventive concept;

FIG. 20 is a schematic top view of a substrate that is in a process of manufacturing a semiconductor device according to an embodiment of the present inventive concept;

FIG. 21 is a schematic top view of a semiconductor package including a semiconductor device according to an embodiment of the present inventive concept; and

FIG. 22 is a schematic cross-sectional view taken along a line I-I′ of FIG. 21.

### DETAILED DESCRIPTION OF THE EMBODIMENTS

Hereinafter, embodiments of the present inventive concept will be described in detail with reference to the accompanying drawings. However, various modifications and changes may be made to the embodiments and the scope of the patent application is not limited or circumscribed by these embodiments. It is to be understood that any modifications, equivalents, or substitutions to the embodiments are included in the scope of the claims.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items.

Terms, such as those defined in commonly used dictionaries, should be construed to have meanings matching with contextual meanings in the relevant art and the present inventive concept, and are not to be construed as an ideal or excessively formal meaning unless otherwise defined herein.

In addition, in the following description with reference to the accompanying drawings, identical components are given the same reference numerals regardless of signs in the drawings, and repeated descriptions thereof are omitted or briefly discussed. In addition, to the extent that the description of various elements is omitted, it may be assumed that these elements are at least similar to corresponding elements that have already been described.

Also, terms such as first, second, A, B, (a), (b), and the like may be used to describe components of an embodiment. These terms are intended only to distinguish one component from another, and the nature, sequence, or order of the components is not limited by the terms. In other words, the components are not limited by these terms. Where a component is described as “connected,” “coupled,” or “bonded” to another component, it is to be understood that the component may be directly connected, coupled, or bonded to the other component, or that there may be an intervening component therebetween.

It is also to be understood that the term “about” refers to a range of numbers or values that are considered by a person having ordinary skill in the art to be equivalent to a stated value, in terms of achieving the same function or result. When the term “about” is used in conjunction with a number or value, the term “about” refers to +20% of that number or value, primarily+10% of that number or value, often +5% of that number or value, or +2% of that number or value. Alternatively, the term “about” may also refer to the number or value itself.

As used herein, “A or B,” “at least one of A and B,” “at least one of A or B,” “A, B or C,” “at least one of A, B and C,” and “A, B, or C,” each of which may include any one of the items listed together in the corresponding one of the phrases, or all possible combinations thereof. The terminology used herein is for describing various examples only and is not to be used to limit the disclosure.

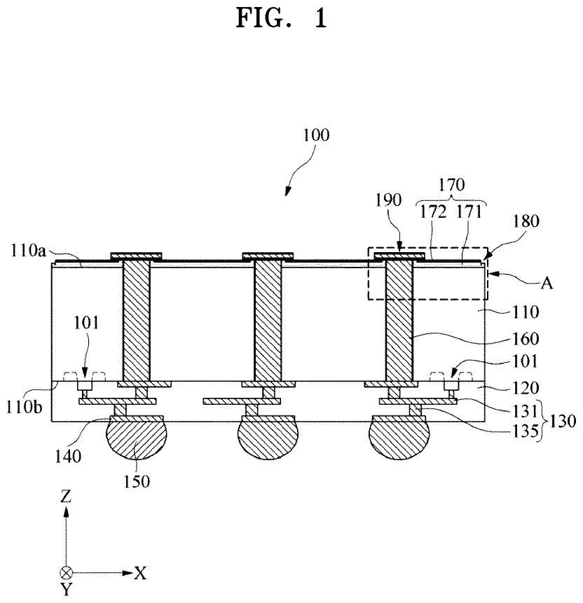

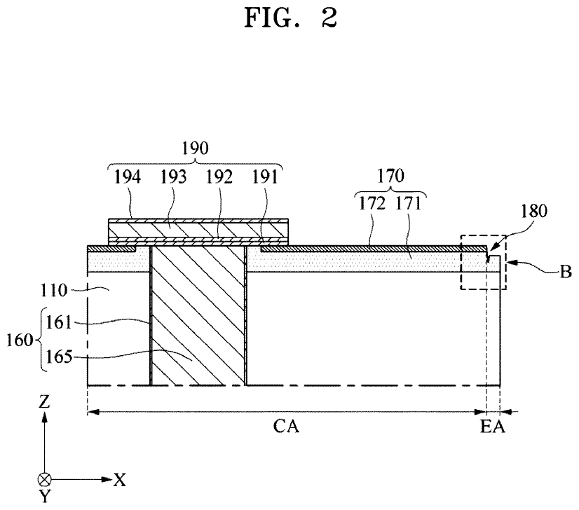

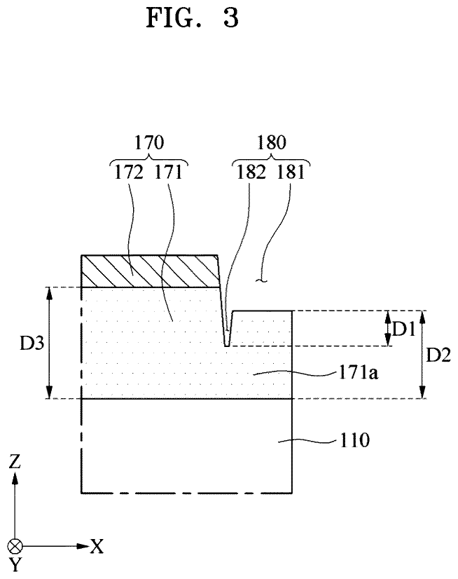

FIG. 1 is a schematic cross-sectional view of a semiconductor device according to an embodiment of the present inventive concept. FIG. 2 is an enlarged view of area A of FIG. 1. FIG. 3 is an enlarged view of area B of FIG. 2.

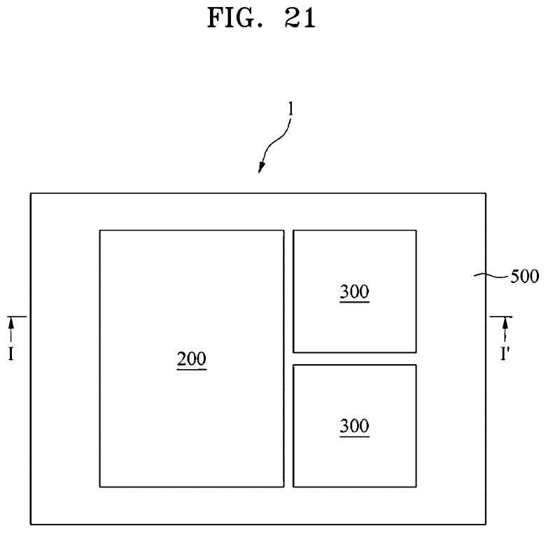

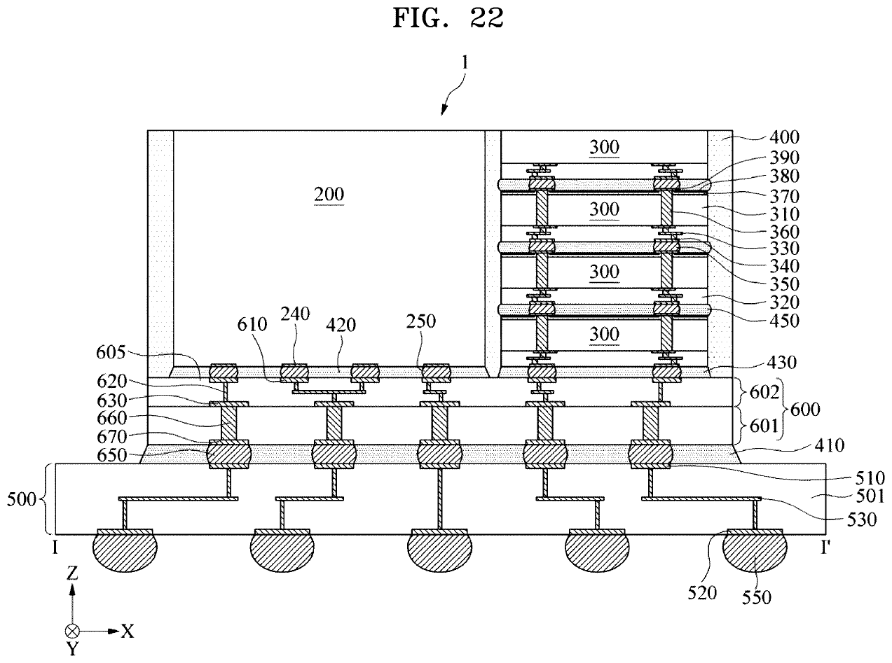

Referring to FIGS. 1 through 3, a semiconductor device 100 may include a substrate 110, a lower insulating layer 120, a wiring structure 130, a lower connecting pad 140, a connecting terminal 150, a via structure 160, an upper insulating layer 170, a recess structure 180, and an upper connecting pad 190. The semiconductor device 100 may be a semiconductor chip including, for example, a memory chip, a logic chip, or a combination thereof. However, the present inventive concept is not limited thereto, and the type of the semiconductor device 100 is not limited thereto. The semiconductor device 100 may be, for example, a first semiconductor chip 200 or a second semiconductor chip 300 in FIGS. 21 and 22.

The substrate 110 may include a top surface 110a and a bottom surface 110b that are opposite each other. For example, in FIG. 1, the top surface 110a may refer to a surface facing in a +Z direction and the bottom surface 110b may refer to a surface facing in a −Z direction. Hereinafter, the +Z direction will be referred to as an upward direction, and the −Z direction will be referred to as a downward direction. The substrate 110 may include a semiconductor material, such as, for example, silicon, germanium, or silicon-germanium. The substrate 110 may be a chip-level substrate, for example.

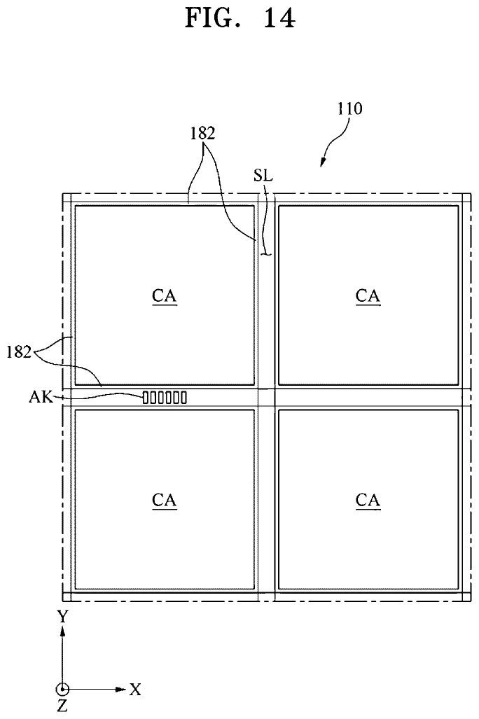

The substrate 110 may include a component area CA and an edge area EA. With the substrate 110 viewed from top, the component area CA may be disposed at the center of the substrate 110. The component area CA may be an area where semiconductor components (or elements) and/or wiring structures are disposed to operate the semiconductor device 100. For example, a transistor 101, the wiring structure 130, the lower connecting pad 140, the connecting terminal 150, the via structure 160, and/or the upper connecting pad 190, which are to be described later, may be disposed in the component area CA. For example, with the substrate 110 viewed from top, the component area CA may have a substantially rectangular shape. The edge area EA may be an area that at least partially surrounds an outer perimeter of the component area CA. For example, the edge area EA may be provided in the form of a substantially rectangular frame. For example, the edge area EA may have a rectangular annular shape. For example, the edge area EA might not include semiconductor components (or elements) and/or wiring structures to operate the semiconductor device 100. The edge area EA may be a portion of a scribe lane SL that remains on the semiconductor device 100 when the substrate 110 is cut along the scribe lane SL (e.g., an SL in FIG. 14) during a process of manufacturing of the semiconductor device 100. In the edge area EA, a test pattern and/or alignment key (e.g., an AK in FIG. 14) formed in the scribe lane SL may remain partially or entirely.

The lower insulating layer 120 may be disposed on the bottom surface 110b of the substrate 110. The lower insulating layer 120 may include an insulating material. The lower insulating layer 120 may include, for example, at least one of silicon oxide, silicon nitride, or silicon oxynitride, or a combination thereof. The lower insulating layer 120 may include a single layer or a plurality of stacked layers.

The wiring structure 130 and the transistor 101 may be disposed in the lower insulating layer 120. The wiring structure 130 may include conductive patterns 131 and conductive vias 135. The conductive vias 135 may penetrate a portion of the lower insulating layer 120 to be electrically connected to the conductive patterns 131. The conductive patterns 131 may be disposed at different levels from each other in the lower insulating layer 120. The conductive patterns 131 and the conductive vias 135 may include a conductive metallic material. The conductive patterns 131 and the conductive vias 135 may include, for example, at least one of copper (Cu), aluminum (Al), tungsten (W), and titanium (Ti), or a combination thereof. The transistor 101 may be provided as a plurality of transistors 101. In this case, at least one of the transistors 101 may be electrically connected to at least one of the conductive vias 135. The lower insulating layer 120 may cover the wiring structure 130 and the transistors 101.

The lower connecting pad 140 may be disposed on a bottom surface of the lower insulating layer 120. The lower connecting pad 140 may be provided as a plurality of lower connecting pads 140. In this case, each of the lower connecting pads 140 may be electrically connected to a corresponding conductive via 135 of the conductive vias 135. The lower connecting pads 140 may include a conductive metallic material. The lower connecting pads 140 may include, for example, at least one of copper (Cu), nickel (Ni), aluminum (Al), tungsten (W), and titanium (Ti), or a combination thereof.

The connecting terminal 150 may be disposed on the bottom surface of the lower insulating layer 120. The connecting terminal 150 may be provided as a plurality of connecting terminals 150. The connecting terminals 150 may include, for example, solder balls, bumps, pillars, or combinations thereof. The connecting terminals 150 may include a conductive metallic material. The connecting terminals 150 may include, for example, at least one of tin (Sn), lead (Pb), silver (Ag), zinc (Zn), nickel (Ni), gold (Au), copper (Cu), aluminum (Al), and bismuth (Bi), or combinations thereof.

The via structure 160 may be disposed in the substrate 110. The via structure 160 may penetrate the substrate 110 and the upper insulating layer 170 in a vertical direction (e.g., the Z direction). The via structure 160 may be electrically connected to the wiring structure 130. The via structure 160 may be provided as a plurality of via structures 160. The via structures 160 and the connecting terminals 150 may transfer electrical signals to or from the semiconductor device 100.

The via structure 160 may include a through via 165 and a via insulating film 161. The through via 165 may penetrate the substrate 110 and the upper insulating layer 170 in the vertical direction (e.g., the Z direction). The through via 165 may include a conductive metallic material. The through via 165 may include, for example, at least one of copper (Cu), aluminum (Al), tungsten (W), or titanium (Ti), or a combination thereof. The via insulating film 161 may at least partially surround an outer side surface of the through via 165. For example, the via insulating film 161 may be disposed between the substrate 110 and the through via 165 and between the upper insulating layer 170 and the through via 165. The via insulating film 161 may include an insulating material. The via insulating film 161 may include, for example, at least one of an oxide, a nitride, a silicon oxide, or a silicon nitride, or a combination thereof.

The upper insulating layer 170 may be disposed on the top surface 110a of the substrate 110. The upper insulating layer 170 may include an insulating material. The upper insulating layer 170 may include, for example, at least one of a silicon oxide, a silicon nitride, or a silicon oxynitride, or a combination thereof. The upper insulating layer 170 may include a single layer or a plurality of stacked layers. For example, the upper insulating layer 170 may include a first upper insulating layer 171 and a second upper insulating layer 172.

The first upper insulating layer 171 may be disposed on the top surface 110a of the substrate 110. The second upper insulating layer 172 may be disposed on a top surface of the first upper insulating layer 171. The first upper insulating layer 171 and the second upper insulating layer 172 may include different insulating materials from each other. For example, the first upper insulating layer 171 may include an oxide and/or silicon oxide. For example, the second upper insulating layer 172 may include a nitride and/or silicon nitride. However, the present inventive concept is not limited thereto, and materials of the first upper insulating layer 171 and the second upper insulating layer 172 are not limited thereto. A thickness of the first upper insulating layer 171 may be greater than a thickness of the second upper insulating layer 172. For example, the thickness of the first upper insulating layer 171 may be about 1 micrometer (μm) to about 3 μm. For example, the thickness of the second upper insulating layer 172 may be about 0.1 μm to about 0.6 μm. However, the present inventive concept is not limited thereto, and the thickness of the first upper insulating layer 171 and the thickness of the second upper insulating layer 172 are not limited thereto.

The upper connecting pad 190 may be disposed on the upper insulating layer 170 to be connected to the via structure 160. For example, the upper connecting pad 190 may be disposed at a position corresponding to the via structure 160. The upper connecting pad 190 may be provided as a plurality of upper connecting pads 190. In this case, the upper connecting pads 190 may each be disposed on a corresponding via structure 160 to be electrically connected to the via structure 160. The upper connecting pad 190 may be exposed on a top surface of the semiconductor device 100. However, the present inventive concept is not limited thereto, and the upper connecting pad 190 may be partially covered by a protective layer. The upper connecting pad 190 may include a conductive metallic material. The upper connecting pad 190 may include, for example, at least one metal selected from copper (Cu), nickel (Ni), titanium (Ti), gold (Au), aluminum (Al), and tungsten (W), or a combination thereof.

The upper connecting pad 190 may include a first pad pattern 191, a second pad pattern 192, a third pad pattern 193, and a fourth pad pattern 194 that are stacked sequentially on each other. The first pad pattern 191 may include, for example, titanium (Ti) and/or copper (Cu). The second pad pattern 192 may include, for example, copper (Cu). The third pad pattern 193 may include, for example, nickel (Ni) and/or copper (Cu). The fourth pad pattern 194 may include, for example, gold (Au) and/or copper (Cu). However, the present inventive concept is not limited thereto, and the structure and/or material of the upper connecting pad 190 is not limited thereto.

The recess structure 180 may be formed in the edge area EA. The recess structure 180 may be formed along an outermost perimeter of the substrate 110. For example, the recess structure 180 may be formed in a direction that is substantially parallel to a side of the substrate 110. The recess structure 180 may represent a space that is formed as the upper insulating layer 170 is recessed. The recess structure 180 may include a recess 181 and a trench 182.

The recess 181 may represent a space that is formed as the upper insulating layer 170 is recessed downward along the outermost perimeter of the substrate 110 in the edge area EA. For example, the recess 181 may be formed in the upper insulating layer 170 that is in the edge area EA. For example, the recess 181 may be formed by being recessed downward from a top surface of the second upper insulating layer 172. For example, the recess 181 may penetrate the second upper insulating layer 172 to be recessed downward further from the top surface of the first upper insulating layer 171. For example, at a position where the recess 181 is formed, the second upper insulating layer 172 may be entirely removed and the first upper insulating layer 171 may partially remain. Hereinafter, a portion of the first upper insulating layer 171 that remains at the position where the recess 181 is formed will be referred to as a stepped insulating layer 171a, for ease of explanation. A top surface of the stepped insulating layer 171a may be formed as a substantially horizontal plane. The top surface of the stepped insulating layer 171a may be positioned at a lower height than the top surface of the first upper insulating layer 171 that is disposed in the component area CA. A thickness of the stepped insulating layer 171a may be less than that of the first upper insulating layer 171 that is disposed in the component area CA.

The trench 182 may represent a space formed as the upper insulating layer 170 is recessed downward between the component area CA and the recess 181, and recessed deeper than the recess 181, in the edge area EA. For example, the trench 182 may be formed in the upper insulating layer 170 in the edge area EA and between the recess 181 and the component area CA. For example, the trench 182 may be formed by being recessed downward from the top surface of the second upper insulating layer 172. For example, the trench 182 may penetrate the second upper insulating layer 172 to be recessed further downward from the top surface of the first upper insulating layer 171. In this case, a depth of the trench 182 being recessed from the top surface of the upper insulating layer 170 may be less than a thickness of the upper insulating layer 170. For example, at a position where the trench 182 is formed, the second upper insulating layer 172 may be entirely removed and the first upper insulating layer 171 may partially remain.

The trench 182 may be disposed to at least partially surround the component area CA from the outside. The trench 182 may be provided in a shape that narrows in width toward the bottom thereof. For example, the trench 182 may be provided in a wedge shape with both sides inclined or slanted toward each other while extending in a thickness direction (e.g., the Z direction) of the semiconductor device 100. For example, the sides of the trench 182 may have the same or different inclination angles. For example, the sides of the trench 182 may be substantially flat or gently curved (e.g., convex toward the bottom). However, the present inventive concept is not limited thereto, and the shape of the trench 182 is not limited thereto.

A depth D1 of the trench 182 being recessed downward from the top surface of the stepped insulating layer 171a may be about ⅖ times a thickness D2 of the stepped insulating layer 171a or less, or about ⅓ times the thickness D2 or less. For example, the thickness D2 of the stepped insulating layer 171a may be about 0.6 μm or less, and the depth D1 of the trench 182 being recessed downward from the top surface of the stepped insulating layer 171a may be about 0.2 μm or less. The depth D1 of the trench 182 being recessed downward from the top surface of the stepped insulating layer 171a may be about ¼ times or less, about ⅕ times or less, about ⅛ times or less, about 1/15 times or less, or about 1/20 times or less a thickness D3 of the first upper insulating layer 171 that is disposed in the component area CA. However, the present inventive concept is not limited thereto, and the recessed depth of the trench 182 is not limited thereto.

The trench 182 may be provided to prevent a crack from spreading into the component area CA when cutting the substrate 110 along the scribe lane (e.g., the SL in FIG. 14) in the process of manufacturing the semiconductor device 100.

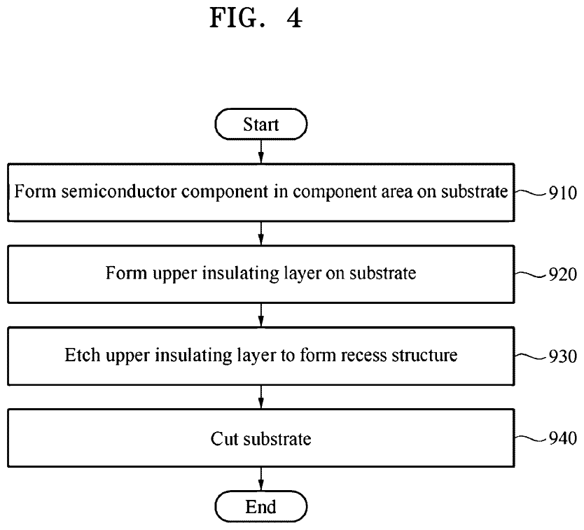

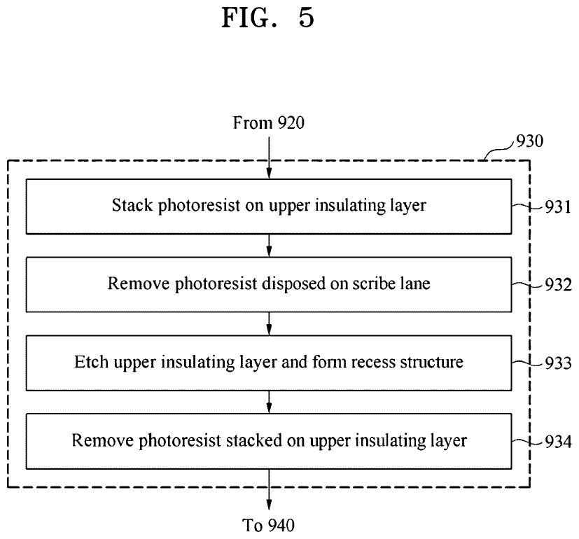

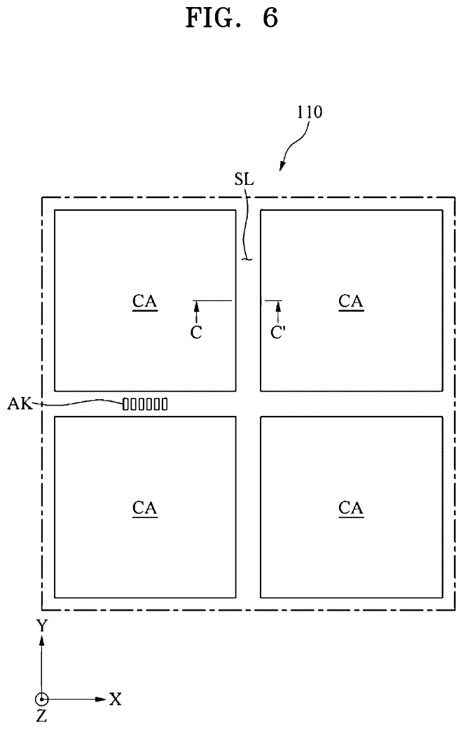

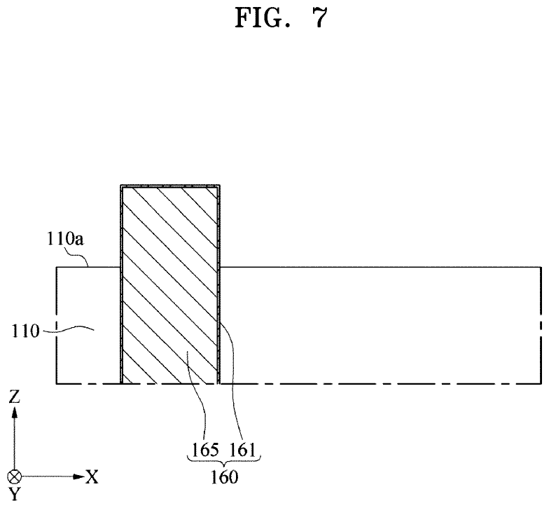

FIG. 4 is a flowchart illustrating a method of manufacturing a semiconductor device according to an embodiment of the present inventive concept. FIG. 5 is a flowchart illustrating a method of forming a recess structure according to an embodiment of the present inventive concept. FIG. 6 is a schematic top view of a substrate being in a process of manufacturing a semiconductor device according to an embodiment of the present inventive concept. FIGS. 7 through 13 are cross-sectional views of an area corresponding to the cross-sectional view taken along a line C-C′ of FIG. 6, illustrating a process of forming a recess structure according to an embodiment of the present inventive concept. FIG. 14 is a schematic top view of a substrate with a trench formed according to an embodiment of the present inventive concept.

Hereinafter, a method of manufacturing a semiconductor device and a method of forming a recess structure according to an embodiment of the present inventive concept will be described with reference to FIGS. 4 through 14.

According to an embodiment, a method 900 of manufacturing a semiconductor device may be performed to manufacture the semiconductor device 100 described above with reference to FIGS. 1 through 3. The method 900 of manufacturing the semiconductor device may include the following: step 910 of forming a semiconductor component (or element) in a component area on a substrate; step 920 of forming an upper insulating layer on the substrate; step 930 of etching the upper insulating layer to form a recess structure; and step 940 of cutting the substrate.

Step 910 may be to form a semiconductor component in a plurality of component areas CAs that are spaced apart from each other to be arranged in the form of a grid on the substrate 110. The substrate 110 in the step 910 may refer to a wafer-level substrate as shown in FIG. 6. The plurality of component areas CAs may be spaced apart from each other and may be arranged in the form of a grid on the substrate 110. In the component areas CAs, semiconductor components (or elements) and/or wiring structures may be formed. The component areas CAs may be delimited by a scribe lane SL. The scribe lane SL may be disposed between the plurality of component areas CAs. The scribe lane SL may be positioned to surround an outer perimeter of each component area CA. For example, each component area CA may have a substantially rectangular shape, and the scribe lane SL may have a substantially rectangular frame shape or a rectangular annular shape. For example, on the scribe lane SL, there may be no semiconductor components and/or wiring structures for operating the semiconductor device (e.g., the semiconductor device 100 in FIG. 1). On the scribe lane SL, however, a configuration or component used in the process of manufacturing the semiconductor device 100 may be formed. For example, on the scribe lane SL, a test pattern and/or an alignment key AK may be formed. The test pattern may be a configuration for testing operations of semiconductor components and/or wiring structures formed in a component area CA during the process of manufacturing the semiconductor device 100. The alignment key AK may be a configuration for aligning a position of the substrate 110 during the process of manufacturing the semiconductor device 100.

On a bottom surface (e.g., the bottom surface 110b in FIG. 1) of the substrate 110, a lower insulating layer (e.g., the lower insulating layer 120 in FIG. 1), a wiring structure (e.g., the wiring structure 130 in FIG. 1), and connecting pads (e.g., the connecting pad 140 in FIG. 1) may be formed. In the component area CA of the substrate 110, a via structure 160 may be formed. The via structure 160 may include a through via 165 and a via insulating film 161. As shown in FIG. 7, an etching and/or grinding process may be performed on the top surface 110a of the substrate 110 to expose a top portion of the via structure 160 such that the via structure 160 extends beyond the top surface 110a of the substrate 110.

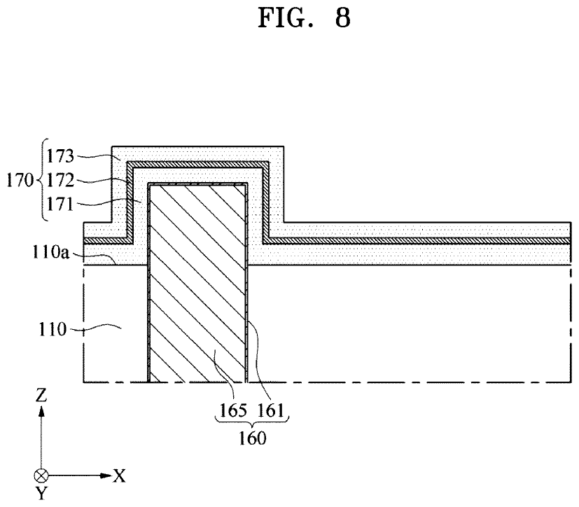

Step 920 may be to form the upper insulating layer 170 on the substrate 110. For example, as shown in FIG. 8, the upper insulating layer 170 may include a first upper insulating layer 171, a second upper insulating layer 172, and a third upper insulating layer 173. The first upper insulating layer 171, the second upper insulating layer 172, and the third upper insulating layer 173 may be formed sequentially on the top surface 110a of the substrate 110 and the via structure 160. For example, the first upper insulating layer 171, the second upper insulating layer 172, and the third upper insulating layer 173 may be formed by a chemical vapor deposition (CVD), atomic layer deposition (ALD), and/or physical vapor deposition (PVD) process. The first upper insulating layer 171 and the third upper insulating layer 173 may include, for example, an oxide and/or silicon oxide. The second upper insulating layer 172 may include, for example, a nitride and/or silicon nitride. However, the present inventive concept is not limited thereto, and the materials of the first upper insulating layer 171, the second upper insulating layer 172, and the third upper insulating layer 173 are not limited thereto.

Step 930 may be to form the recess structure 180. Step 930 may also be to etch the upper insulating layer 170 such that the recess structure 180, which surrounds each component area CA on the scribe lane SL that is disposed between the plurality of component areas CA, is formed.

Step 930 may include the following: step 931 of stacking a photoresist on an upper insulating layer; step 932 of removing the photoresist disposed on a scribe lane; step 933 of etching the upper insulating layer to form a recess structure; and step 934 of removing the photoresist that is stacked on the upper insulating layer.

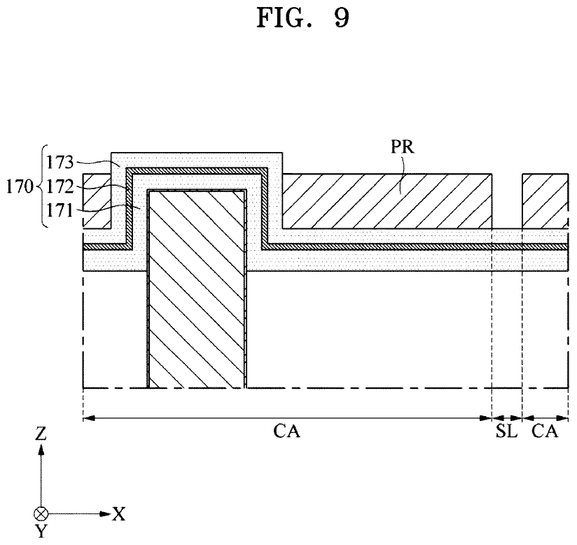

Step 931 may be to stack a photoresist PR on the upper insulating layer 170. Step 932 may be to remove the photoresist PR that is disposed on the scribe lane SL, through an exposure process. As shown in FIG. 9, as the photoresist PR that is disposed on the scribe lane SL is removed in step 932, the upper insulating layer 170 may be exposed in an upward direction (e.g., a +Z direction).

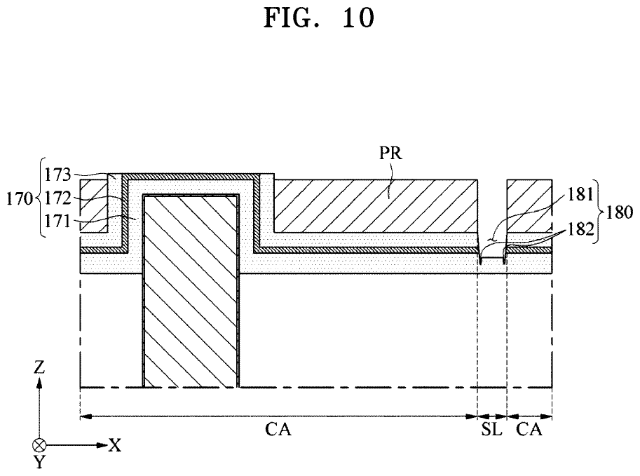

Step 933 may be to etch the upper insulating layer 170 through an etching process and to form the recess structure 180. As shown in FIG. 10, a portion of the upper insulating layer 170 may be etched, and the recess structure 180 may thereby be formed. For example, at a position where the recess structure 180 is formed, both the third upper insulating layer 173 and the second upper insulating layer 172 may be removed entirely, and the first upper insulating layer 171 may partially remain. The recess structure 180 may be formed along the scribe lane SL.

The recess structure 180 may include a recess 181 and a pair of trenches 182. The recess 181 may be formed as the upper insulating layer 170 is recessed along the scribe lane SL. The recess 181 may be formed within the boundaries of the scribe lane SL. For example, the recess 181 may be formed at substantially the center of the scribe lane SL. For example, the recess 181 may be formed by penetrating the third upper insulating layer 173 and the second upper insulating layer 172 to be recessed into a specified depth of the first upper insulating layer 171. A top surface of the upper insulating layer 170 (e.g., the stepped insulating layer 171a in FIG. 3) that remains at the position where the recess 181 is formed may be formed as a substantially horizontal plane.

The pair of trenches 182 may be formed as the upper insulating layer 170 is recessed deeper than the recess 181 along the scribe lane SL and from both sides of the recess 181. Each trench 182 may be disposed between a component area CA and the recess 181. For example, the pair of trenches 182 may be formed by penetrating the third upper insulating layer 173 and the second upper insulating layer 172 to be recessed into a specified depth of the first upper insulating layer 171. Each trench 182 may have a shape (e.g., a wedge shape) that narrows in width toward the bottom thereof.

Step 933 may be performed through a single dry etching process. For example, by adjusting a recipe of a dry etching process, the recess structure 180 may be formed in one step through the single dry etching process. However, the present inventive concept is not limited thereto, and step 933 may also be performed by a single etching process and/or exposure process or by a plurality of etching processes and/or exposure processes.

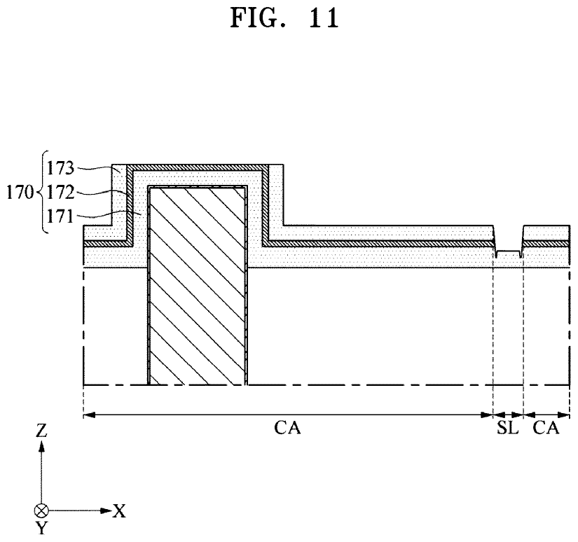

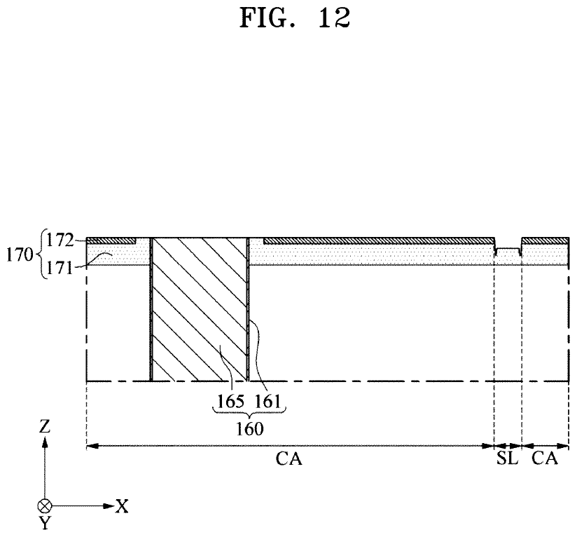

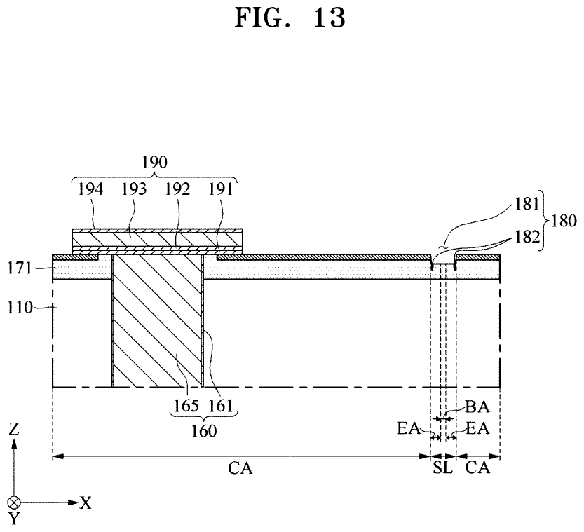

Step 934 may be to remove the photoresist PR that is stacked on the upper insulating layer 170, as shown in FIG. 11. Subsequently, a portion of the upper insulating layer 170 and a portion of the via structure 160 may be removed by a polishing process (e.g., a chemical mechanical polishing (CMP) process), as shown in FIG. 12. For example, the third upper insulating layer 173 may be entirely removed to expose the second upper insulating layer 172 in an upward direction (e.g., the +Z direction). For example, a top portion of the via structure 160 may be partially removed. Subsequently, the upper connecting pad 190 may be formed on the via structure 160 and the upper insulating layer 170, as shown in FIG. 13. The upper connecting pad 190 may be electrically connected to the via structure 160. For example, the upper connecting pad 190 may include a first pad pattern 191, a second pad pattern 192, a third pad pattern 193, and a fourth pad pattern 194 that are stacked sequentially stacked on each other.

Once the trenches 182 are formed in step 930, the trenches 182 may surround each component area CA while in the scribe lane SL, as shown in FIG. 14. For example, a trench 182 may be formed at a position substantially contacting or abutting on an outer perimeter of a component area CA. However, only the positions of the trenches 182 are schematically illustrated in FIG. 14 for ease of explanation, and the recess 181 is omitted from FIG. 14.

Step 940 may be to cut the substrate 110 along the scribe lane SL such that the plurality of component areas CA is separated from each other to form a plurality of semiconductor devices (e.g., the semiconductor device 100 in FIG. 1). For example, step 940 may be construed as a sawing process. For example, step 940 may be performed using a blade and/or a laser. For example, in the structure of FIG. 13, the upper insulating layer 170 and the substrate 110 may be cut along an area where the recess 181 is formed. For example, the upper insulating layer 170 and the substrate 110 may be cut along a center line of the recess 181. By step 940, a breaking area BA which is a portion (e.g., a center area) of the scribe lane SL may be removed, and the upper insulating layer 170 and the substrate 110 may be separated from each other along the breaking area BA to form the plurality of semiconductor devices (e.g., the semiconductor device 100). After step 940, a remaining area in the scribe lane SL, excluding the breaking area BA, may become an edge area EA of the semiconductor device 100. For example, as shown in FIG. 2, in the edge area EA of the semiconductor device 100, at least a portion of the recess structure 180 (e.g., the recess 181 and/or the trench 182) may remain. For example, in the semiconductor device 100 according to an embodiment of the present inventive concept, the recess 181 may be entirely removed from the edge area EA, and only an inner inclined surface of the trench 182 may remain. However, the present inventive concept is not limited thereto. For example, at least a portion of the recess 181 may remain in the edge area EA.

In the process of cutting the upper insulating layer 170 and the substrate 110 in step 940, a crack may be generated in the scribe lane SL. For example, as the upper insulating layer 170 and the substrate 110 are cut along the area where the recess 181 is formed, the first upper insulating layer 171 and/or the substrate 110 disposed in the breaking area BA may be cracked. In this case, the pair of trenches 182 formed on both sides of the recess 181 at a deeper depth than the recess 181 may block or reduce the spread of such a crack, which is generated in the breaking area BA, into the component area CA. This structure may reduce or prevent semiconductor components and/or wiring structures that are formed in the component area CA from being damaged as the crack spreads to the component area CA in the process of cutting the upper insulating layer 170 and the substrate 110. Accordingly, it may increase the reliability of a semiconductor device (e.g., the semiconductor device 100 in FIG. 1) to be manufactured and increase the yield.

The method 900 of manufacturing a semiconductor device described above is provided as an example, and the detailed steps of the method 900 of manufacturing a semiconductor device are not limited to the steps described above. For example, some steps may be omitted or performed in a different order, and other steps not described herein may be performed additionally.

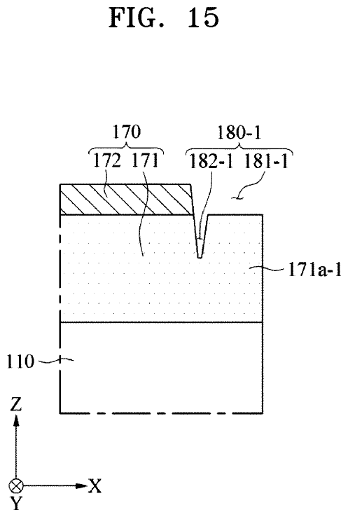

FIGS. 15 through 19 are cross-sectional views of an area corresponding to the area B of FIG. 2, illustrating a portion of a semiconductor device according to an embodiment of the present inventive concept. Descriptions that overlap with what has been described above with reference to FIGS. 1 through 3 will not be repeated in the following description of embodiments provided with reference to FIGS. 15 through 19, and the preceding description provided with reference to FIGS. 1 through 3 will be incorporated by reference to the extent that it is not inconsistent with the following description.

Referring to FIG. 15, in an embodiment of the present inventive concept, a recess structure 180-1 may include a recess 181-1 and a trench 182-1. A depth of the recess 181-1 being recessed downward from the second upper insulating layer 172 may be substantially the same as the thickness of the second upper insulating layer 172. A thickness of a stepped insulating layer 171a-1 remaining at a position where the recess 181-1 is formed may be substantially the same as the thickness of the first upper insulating layer 171 that is disposed in a component area (e.g., the CA in FIG. 2). A top surface of the stepped insulating layer 171a-1 may be formed as a substantially horizontal plane. Alternatively, the depth of the recess 181-1 being recessed downward from the second upper insulating layer 172 may be less than the thickness of the second upper insulating layer 172, and the second upper insulating layer 172 may remain partially at the position where the recess 181-1 is formed. For example, the second upper insulating layer 172 may overlap with the recess 181-1 in a horizontal direction (e.g., the X-direction).

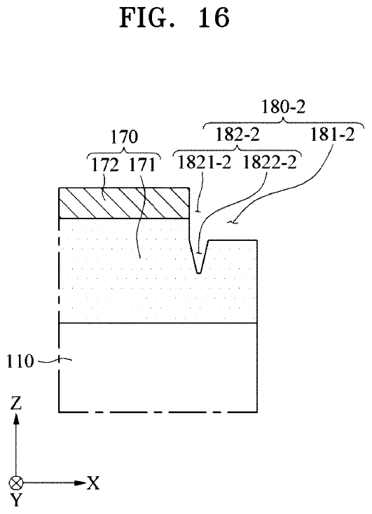

Referring to FIG. 16, in an embodiment of the present inventive concept, a recess structure 180-2 may include a recess 181-2 and a trench 182-2. The trench 182-2 may include a vertical area 1821-2 and a wedge area 1822-2. The vertical area 1821-2 may be an area having a substantially constant width. The wedge area 1822-2 may be an area that narrows in width toward the bottom thereof. The wedge area 1822-2 may be connected to a bottom of the vertical area 1821-2. For example, the vertical area 1821-2 may be formed across the second upper insulating layer 172 and the first upper insulating layer 171, and the wedge area 1822-2 may be formed in the first upper insulating layer 171. In addition, the vertical area 1821-2 may be formed in the second upper insulating layer 172, and the wedge area 1822-2 may be formed across the second upper insulating layer 172 and the first upper insulating layer 171.

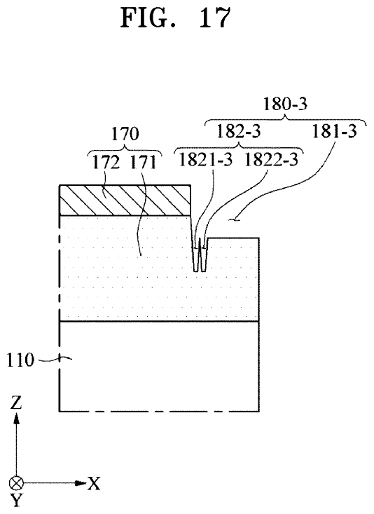

Referring to FIG. 17, in an embodiment of the present inventive concept, a recess structure 180-3 may include a recess 181-3 and a trench 182-3. The trench 182-3 may include a first trench 1821-3 and a second trench 1822-3. The first trench 1821-3 and the second trench 1822-3 may be disposed adjacent to each other in a horizontal direction (e.g., an X direction). For example, the first trench 1821-3 and the second trench 1822-3 may be formed to at least partially overlap each other in the horizontal direction (e.g., the X direction) and/or may be formed to be spaced apart from each other. Depths of the first trench 1821-3 and the second trench 1822-3 being recessed may be substantially the same as each other. In addition, the depths of the first trench 1821-3 and the second trench 1822-3 being recessed may be different from each other. For example, the first trench 1821-3 may be recessed deeper than the second trench 1822-3, or the second trench 1822-3 may be recessed deeper than the first trench 1821-3. In addition, the trench 182-3 may include three or more trenches.

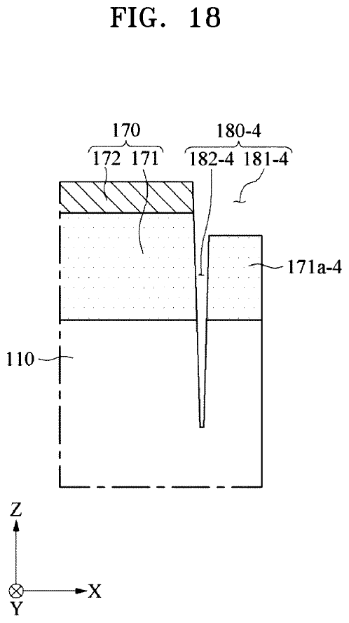

Referring to FIG. 18, in an embodiment of the present inventive concept, a recess structure 180-4 may include a recess 181-4 and a trench 182-4. A depth of the trench 182-4 being recessed downward from the top surface of the upper insulating layer 170 may be greater than the thickness of the upper insulating layer 170. The trench 182-4 may penetrate the upper insulating layer 170 entirely to be recessed downward further from a top surface of the substrate 110. At a position where the recess 181-4 is formed, the second upper insulating layer 172 may be entirely removed, and the first upper insulating layer 171 may partially remain (e.g., a stepped insulating layer 171a-4).

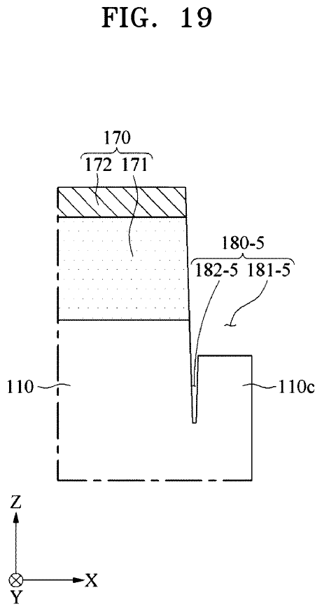

Referring to FIG. 19, in an embodiment of the present inventive concept, a recess structure 180-5 may include a recess 181-5 and a trench 182-5. A depth of the trench 182-5 being recessed downward from the top surface of the upper insulating layer 170 may be greater than the thickness of the upper insulating layer 170. The trench 182-5 may entirely penetrate the upper insulating layer 170 to be recessed downward further from a top surface of the substrate 110. A depth of the recess 181-5 being recessed downward from a top surface of the upper insulating layer 170 may be greater than the thickness of the upper insulating layer 170. The recess 181-5 may entirely penetrate the upper insulating layer 170 to be recessed downward further from the top surface of the substrate 110. For example, a lower surface of the recess 181-5 may be disposed below the first upper insulating layer 171. At a position where the recess 181-5 is formed, both the second upper insulating layer 172 and the first upper insulating layer 171 may be entirely removed, and a top portion of the substrate 110 may be partially removed. When the substrate 110 remaining at the position where the recess 181-5 is formed is referred to as a stepped substrate 110c, the stepped substrate 110c may have a thickness that is less than that of the substrate 110 that is disposed in a component area (e.g., the CA in FIG. 2). For example, a top surface of the stepped substrate 110c may be disposed at a lower height than the top surface of the substrate 110 that is disposed in the component area CA. For example, the top surface of the stepped substrate 110c may be formed as a substantially horizontal plane.

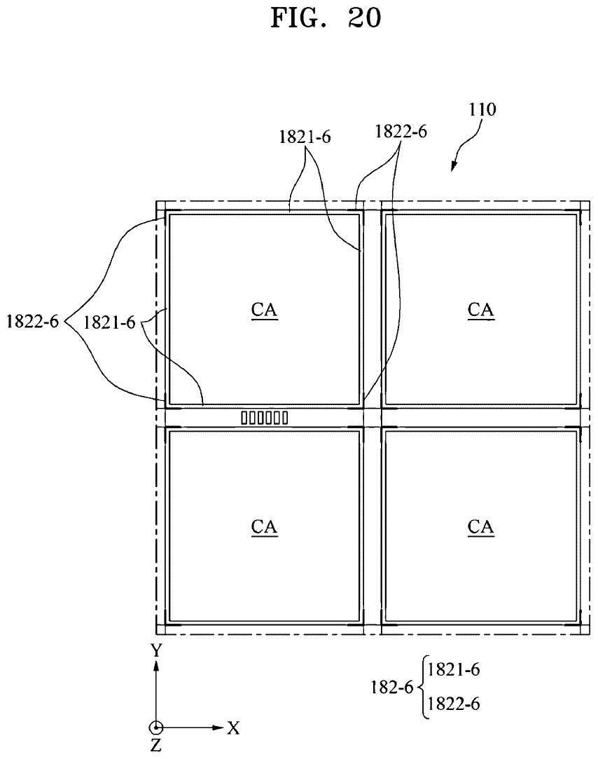

FIG. 20 is a schematic top view of a substrate that is in a process of manufacturing a semiconductor device according to an embodiment of the present inventive concept.

Referring to FIG. 20, in an embodiment of the present inventive concept, a trench 182-6 may include a first trench portion 1821-6 and a second trench portion 1822-6. For example, the first trench portion 1821-6 may be disposed adjacent to a side of a component area CA, and the second trench portion 1822-6 may be disposed adjacent to a corner of the component area CA. The first trench portion 1821-6 and the second trench portion 1822-6 may be formed with different depths from each other. For example, a depth of the second trench portion 1822-6 being recessed may be greater than a depth of the first trench portion 1821-6 being recessed. This structure may form a deeper depth of a trench (e.g., the second trench portion 1822-6) in a portion (e.g., a corner portion) that is vulnerable to a crack spreading and may thus more efficiently prevent the crack from spreading. However, the present inventive concept not limited thereto, and the position of the second trench portion 1822-6 may be set differently depending on a position that is vulnerable to a crack spreading. However, only the position of the trench 182-6 is schematically illustrated in FIG. 20 for ease of explanation, and a recess (e.g., the recess 181 in FIG. 3) is omitted from FIG. 20.

It will be readily understood by a person having ordinary skill in the art that the various embodiments of the present inventive concept described herein with reference to FIGS. 1 through 3 and FIGS. 15 through 20 can be combined with each other without contradicting each other.

FIG. 21 is a schematic top view of a semiconductor package including a semiconductor device according to an embodiment of the present inventive concept. FIG. 22 is a schematic cross-sectional view taken along a line I-I′ of FIG. 21.

Referring to FIGS. 21 and 22, according to an embodiment of the present inventive concept, a semiconductor package 1 may include a package substrate 500, an interposer substrate 600, a first semiconductor chip 200, and a second semiconductor chip 300.

The package substrate 500 may include an insulating base layer 501, package substrate pads 510, terminal pads 520, and package substrate wirings 530. The package substrate 500 may be, for example, a printed circuit board (PCB). The insulating base layer 501 may include a single layer or a plurality of stacked layers. The package substrate pads 510 may be disposed on a top surface of the package substrate 500. The terminal pads 520 may be disposed on a bottom surface of the package substrate 500. The package substrate wirings 530 may be disposed in the insulating base layer 501. The package substrate wirings 530 may be electrically connected to the package substrate pads 510 and the terminal pads 520. The package substrate pads 510, the terminal pads 520, and the package substrate wirings 530 may each include a conductive metallic material. For example, the package substrate pads 510, the terminal pads 520, and the package substrate wirings 530 may each include at least one of copper (Cu), aluminum (Al), tungsten (W), and titanium (Ti), or a combination thereof.

External terminals 550 may be disposed on the bottom surface of the package substrate 500. For example, the external terminals 550 may be disposed on a bottom surface of the terminal pads 520. The external terminals 550 may be electrically connected to the package substrate wirings 530. The external terminals 550 may be interfaced with external devices. Accordingly, external electrical signals may be transmitted to and received by the package substrate pads 510 via the external terminals 550. For example, the external terminals 550 may include solder balls and/or solder bumps. The external terminals 550 may include a conductive metallic material. For example, the external terminals 550 may include at least one of tin (Sn), lead (Pb), silver (Ag), zinc (Zn), nickel (Ni), gold (Au), copper (Cu), aluminum (Al), and bismuth (Bi), or a combination thereof.

The interposer substrate 600 may be disposed on the package substrate 500. The interposer substrate 600 may include a substrate layer 601 and a wiring layer 602 on the substrate layer 601.

The substrate layer 601 may include a plurality of through electrodes 660 and lower pads 670. The substrate layer 601 may be, for example, a silicon (Si) substrate. The through electrodes 660 may be disposed in the substrate layer 601 and may penetrate the substrate layer 601. Each of the through electrodes 660 may be electrically connected to a corresponding upper substrate wiring 630 of upper substrate wirings 630 which will be described later. The lower pads 670 may be disposed on a bottom surface of the substrate layer 601. The lower pads 670 may be electrically connected to the through electrodes 660. The plurality of through electrodes 660 and lower pads 670 may each include a conductive metallic material. For example, the plurality of through electrodes 660 and lower pads 670 may include at least one of copper (Cu), aluminum (Al), tungsten (W), and titanium (Ti), or a combination thereof.

The wiring layer 602 may include upper pads 610, internal wirings 620, the upper substrate wirings 630, and a wiring insulating layer 605. The wiring insulating layer 605 may cover the upper pads 610, the internal wirings 620, and the upper substrate wirings 630. For example, the wiring insulating layer 605 may cover side surfaces and a lower surface of each of the upper pads 610 and may cover side surfaces and an upper surface of each of the upper substrate wirings 630. The upper pads 610 may be disposed on a top surface of the wiring layer 602, and the upper substrate wirings 630 may be disposed on a bottom surface of the wiring layer 602. The upper pads 610 may be exposed on the top surface of the wiring layer 602, and the upper substrate wirings 630 may be exposed at the bottom surface of the wiring layer 602. The internal wirings 620 may be disposed in the wiring insulating layer 605 and may be electrically connected to the upper pads 610 and the upper substrate wirings 630. The upper pads 610, the internal wirings 620, and the upper substrate wirings 630 may each include a conductive metallic material. For example, the upper pads 610, the internal wirings 620, and the upper substrate wirings 630 may each include at least one of copper (Cu), aluminum (Al), tungsten (W), and titanium (Ti), or a combination thereof.

Substrate bumps 650 may be disposed between the package substrate 500 and the interposer substrate 600. The substrate bumps 650 may electrically connect the package substrate 500 and the interposer substrate 600 to each other. Each of the lower pads 670 may be electrically connected to a corresponding package substrate pad 510 via a corresponding one of the substrate bumps 650. The substrate bumps 650 may include a conductive material and may be provided in the form of at least one of a solder ball, bump, or pillar. For example, a pitch of the substrate bumps 650 may be smaller than a pitch of the external terminals 550.

A substrate underfill 410 may be disposed between the package substrate 500 and the interposer substrate 600. The substrate underfill 410 may fill a space between the substrate bumps 650 to seal the substrate bumps 650. For example, the substrate underfill 410 may include a non-conductive film (NCF), such as, for example, an Ajinomoto build-up film (ABF).

The first semiconductor chip 200 may be mounted on the interposer substrate 600. The first semiconductor chip 200 may include a logic chip, a buffer chip, or a system-on-chip (SOC). For example, the first semiconductor chip 200 may be an application specific integrated circuit (ASIC) chip or an application processor (AP) chip. The first semiconductor chip 200 may include a central processing unit (CPU) or a graphics processing unit (GPU).

The first semiconductor chip 200 may include first chip pads 240 that are disposed on a bottom surface of the first semiconductor chip 200. The first chip pads 240 may be electrically connected to corresponding upper pads 610 of the interposer substrate 600. The first chip pads 240 may include a conductive metallic material, such as, for example, at least one of copper (Cu), aluminum (Al), tungsten (W), and titanium (Ti), or a combination thereof.

A plurality of second semiconductor chips 300 may be mounted on the interposer substrate 600. The second semiconductor chips 300 may be disposed to be horizontally spaced apart from the first semiconductor chips 200. The second semiconductor chips 300 may be vertically stacked on the interposer substrate 600 to form a chip stack. For example, the chip stack may be provided as a plurality of chip stacks. The second semiconductor chips 300 may be of a type that is different from that of the first semiconductor chip 200. The second semiconductor chips 300 may be memory chips. The memory chips may include high bandwidth memory (HBM). The second semiconductor chips 300 may include, for example, dynamic random-access memory (DRAM) chips. However, the structures illustrated in the accompanying drawings are provided only as examples, and the number and/or arrangement of the chip stacks, the first semiconductor chip 200, and the second semiconductor chips 300 may vary.

The second semiconductor chips 300 may each include a chip substrate 310, a chip insulating layer 320, chip wirings 330, integrated circuits (ICs), second chip pads 340, chip vias 360, a first passivation pattern 370, a second passivation pattern 380, and chip pad structures 390. The chip insulating layer 320 may be disposed on a bottom surface of the chip substrate 310. The chip wirings 330 may be disposed in the chip insulating layer 320. For example, the ICs may be provided in the chip insulating layer 320. The second chip pads 340 may be disposed on a bottom surface of the second semiconductor chips 300. The second chip pads 340 may be electrically connected to corresponding upper pads 610 of the interposer substrate 600. The second chip pads 340 may include a conductive metallic material, such as, for example, at least one of copper (Cu), aluminum (Al), tungsten (W), and titanium (Ti), or a combination thereof. The first passivation pattern 370 may be disposed on a top surface of the chip substrate 310. The second passivation pattern 380 may be disposed on the first passivation pattern 370. The chip vias 360 may penetrate the chip substrate 310 and the first passivation pattern 370 to be electrically connected to the chip wirings 330. The chip pad structures 390 may be disposed on the chip vias 360.

The chip substrate 310, the chip insulating layer 320, the chip wirings 330, the second chip pads 340, the chip vias 360, the first passivation pattern 370, the second passivation pattern 380, and the chip pad structures 390 may be substantially the same as the substrate 110, the lower insulating layer 120, the wiring structure 130, the lower connecting pad 140, the connecting terminal 150, the via structure 160, the first upper insulating layer 171, the second upper insulating layer 172, and the upper connecting pad 190, respectively, which are described above with reference to FIGS. 1 through 3. However, in an embodiment of the present inventive concept, an uppermost second semiconductor chip 300 of the second semiconductor chips 300 might not include the chip vias 360.

In addition, upper bumps 350 may be disposed between two neighboring second semiconductor chips 300 of the second semiconductor chips 300. The upper bumps 350 may be electrically connected to the chip vias 360 of corresponding second semiconductor chips 300 of the second semiconductor chips 300. The upper bumps 350 may electrically connect the second semiconductor chips 300 to each other.

An underfill 450 may be disposed between two neighboring second semiconductor chips 300 of the second semiconductor chips 300. The underfill 450 may fill a space between the upper bumps 350 to seal the upper bumps 350. The underfill 450 may include, for example, an NCF such as an ABF.

In addition, chip bumps 250 may be disposed between the interposer substrate 600 and the first semiconductor chip 200 and between the interposer substrate 600 and a lowermost second semiconductor chip 300 of the second semiconductor chips 300. The chip bumps 250 may electrically connect the interposer substrate 600 and the first semiconductor chip 200 to each other, and may electrically connect the interposer substrate 600 and the lowermost second semiconductor chip 300 to each other. The first chip pads 240 of the first semiconductor chip 200 and the second chip pads 340 of the lowermost second semiconductor chip 300 may each be electrically connected to a corresponding upper pad 610 via a corresponding one of the chip bumps 250. The chip bumps 250 may include a conductive material and may be provided in the form of at least one of a solder ball, bump, or pillar, or a combination thereof. For example, a pitch of the chip bumps 250 may be smaller than a pitch of the substrate bumps 650.

A first chip underfill 420 may be disposed between the interposer substrate 600 and the first semiconductor chip 200. A second chip underfill 430 may be disposed between the interposer substrate 600 and the second semiconductor chips 300. The first chip underfill 420 and the second chip underfill 430 may fill a space between the chip bumps 250 to seal the chip bumps 250. The first chip underfill 420 and the second chip underfill 430 may each include, for example, an NCF such as an ABF.

A molding film 400 may be provided on the interposer substrate 600. The molding film 400 may cover the top surface of the interposer substrate 600, a sidewall of the first semiconductor chip 200, and sidewalls of the second semiconductor chips 300. In an embodiment of the present inventive concept, the molding film 400 may expose a top surface of the first semiconductor chip 200 and a top surface of the uppermost second semiconductor chip 300. The molding film 400 may include an insulating polymer, such as, an epoxy molding compound (EMC).

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor device, comprising:
a substrate comprising a component area and an edge area at least partially surrounding an outer perimeter of the component area;
an upper insulating layer disposed on a first surface of the substrate;
a recess formed in the upper insulating layer and extends downward along an outermost perimeter of the substrate in the edge area; and
a trench formed in the upper insulating layer between the component area and the recess, and recessed downward beyond the recess, in the edge area.

2. The semiconductor device of claim 1, wherein the trench is disposed to at least partially surround the component area.

3. The semiconductor device of claim 1, wherein the trench includes a shape that has a width that narrows toward a bottom thereof.

4. The semiconductor device of claim 3, wherein the trench is provided in a wedge shape with both sides inclined relative to a thickness direction of the semiconductor device.

5. The semiconductor device of claim 1, wherein a depth of the trench being recessed from a first surface of the upper insulating layer is less than a thickness of the upper insulating layer.

6. The semiconductor device of claim 1, wherein the upper insulating layer comprises:
a first upper insulating layer disposed on the substrate; and
a second upper insulating layer disposed on the first upper insulating layer.

7. The semiconductor device of claim 6, wherein the recess penetrates the second upper insulating layer to be recessed further downward from the first surface of the first upper insulating layer.

8. The semiconductor device of claim 7, wherein a portion of the first upper insulating layer that remains at a position where the recess is formed is a stepped insulating layer, and a depth of the trench being recessed downward from a first surface of the stepped insulating layer is less than or equal to ⅖ times a thickness of the stepped insulating layer.

9. The semiconductor device of claim 7, wherein a portion of the first upper insulating layer that remains at a position where the recess is formed is a stepped insulating layer, and a depth of the trench being recessed downward from a first surface of the stepped insulating layer is less than or equal to ¼ times a thickness of the first upper insulating layer that is disposed in the component area.

10. The semiconductor device of claim 1, wherein the trench comprises a vertical area, which has a substantially constant width, and a wedge area that narrows in width toward a bottom thereof.

11. The semiconductor device of claim 1, wherein the trench comprises a first trench and a second trench that are disposed to be adjacent to each other in a horizontal direction.

12. The semiconductor device of claim 11, wherein the first trench and the second trench have a same or different depths of being recessed.

13. The semiconductor device of claim 1, wherein the trench penetrates the upper insulating layer to be recessed downward further from the first surface of the substrate.

14. The semiconductor device of claim 13, wherein the recess penetrates the upper insulating layer to be recessed further downward from the first surface of the substrate.

15. The semiconductor device of claim 1, wherein the trench comprises:
a first trench portion adjacent to a side of the component area; and
a second trench portion adjacent to a corner of the component area,
wherein a depth of the second trench portion being recessed is greater than a depth of the first trench portion being recessed.

16. A method of manufacturing a semiconductor device, the method comprising:
forming a semiconductor component in a plurality of component areas that are arranged on a substrate, wherein the plurality of component areas are spaced apart from each other in the form of a grid;
forming an upper insulating layer on the substrate;
etching the upper insulating layer to form a recess structure that at least partially surrounds each of the component areas, wherein the recess structure is formed on a scribe lane that is disposed between the plurality of component areas; and
cutting the substrate along the scribe lane to separate the plurality of component areas from each other and form a plurality of semiconductor devices,
wherein the recess structure comprises:
a recess formed as the upper insulating layer is recessed along the scribe lane; and
a pair of trenches formed as the upper insulating layer is recessed along the scribe lane on both sides of the recess, and recessed deeper than the recess.

17. The method of claim 16, wherein the etching of the upper insulating layer to form the recess structure comprises:
stacking a photoresist on the upper insulating layer;
removing the photoresist that is disposed on the scribe lane, through an exposure process;
etching the upper insulating layer and forming the recess structure, through an etching process; and
removing the photoresist that is stacked on the upper insulating layer.

18. The method of claim 17, wherein the forming of the recess structure is performed through a dry etching process.

19. The method of claim 16, wherein the cutting of the substrate comprises:
cutting the substrate along an area in which the recess is formed.

20. The method of claim 16, wherein each of the trenches in the pair is provided in a shape that narrows in width toward a bottom thereof.
